(19) United States
(12) Patent Application Publication
(10) Pub. No.: US 2007/0194321 A1
(43) Pub. Date: Aug. 23, 2007

(54) LIGHT EMITTING ELEMENT, LIGHT EMITTING DEVICE, AND ELECTRONIC DEVICE

(75) Inventors: Shunpei YAMAZAKI, Tokyo (JP); Junichiro SAKATA, Atsugi (JP); Takahiro KAWAKAMI, Isehara (JP); Yoshiaki YAMAMOTO, Atsugi (JP); Miki KATAYAMA, Atsugi (JP); Kohei YOKOYAMA, Ayase (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/673,153

(22) Filed: Feb. 9, 2007

(30) Foreign Application Priority Data
Feb. 17, 2006 (JP) 2006-041644

(51) Int. Cl. H01L 29/04

(52) U.S. Cl. 257/72; 257/83; 257/E27.132

(57) ABSTRACT

It is an object of the present invention to provide a light emitting element which can be driven at a low voltage. Other objects of the present invention are to provide a light emitting element with a high luminescent efficiency; a light emitting element with a high luminance; a light emitting element having long-life luminescence; a light emitting element and an electronic device having reduced power consumption; and a light emitting element and an electronic device which can be manufactured at low cost. The light emitting element has a light emitting layer and a barrier layer between a first electrode and a second electrode, the light emitting layer contains a base material and an impurity element, and the barrier layer is provided so as to be in contact with the first electrode. Light emission is obtained when a voltage is applied such that a potential of the second electrode becomes higher than a potential of the first electrode.

### BACKGROUND OF THE INVENTION

1. Field of the Invention

The present invention relates to a light emitting element utilizing electroluminescence. In addition, the present invention relates to a light emitting device and an electronic device each having the light emitting element.

2. Description of the Related Art

In recent years, thin and flat display devices are required as display devices for televisions, cellular phones, digital cameras, and the like. A display device utilizing a self-luminous light emitting element is attracting attention as a display device for meeting this requirement. A light emitting element utilizing electroluminescence is one the self-luminescent light emitting elements in which a light emitting material is interposed between a pair of electrodes and a voltage is applied thereto so that light emission from the light emitting material can be obtained.

A self-luminous light emitting element like this has advantages over a liquid crystal display element, such as high visibility of the pixel and no need of backlight, and is considered suitable for a flat panel display element. In addition, a light emitting element like this can be manufactured to be thin and light-weight, which is also a great advantage. Furthermore, the response speed is extremely high, which is another feature of this light emitting element.

Furthermore, a self-luminous light emitting element like this can be formed into a film; therefore, by forming an element with a large area, plane light emission can be easily obtained. It is difficult to obtain this feature from a point light source typified by an incandescent lamp or an LED, or a line light source typified by a fluorescent lamp. Accordingly, a utility value of the self-luminescent light emitting element as a plane light source which can be applied to a lighting system and the like is high.

Light emitting elements utilizing electroluminescence are classified according to whether the light emitting material is an organic compound or an inorganic compound. In general, the former is referred to as an organic EL element, and the latter is referred to as an inorganic EL element.

Inorganic EL elements are classified as a dispersed inorganic EL element and a thin-film inorganic EL element depending on their element structures. They are different from each other in that the former includes a light emitting layer in which particles of a light emitting material are dispersed in a binder while the latter includes a light emitting layer formed of a thin film of a phosphor material. However, their mechanisms are common in that light emission is obtained through collision excitation by the acceleration of electrons in a high electric field of a base material or a luminescent center. For such a reason, a high electric field is necessary for a general inorganic EL element to provide light emission, and it is necessary to apply a voltage of several hundred volts to a light emitting element. For example, an inorganic EL element that emits high luminance blue light which is necessary for a full-color display has been developed in recent years; however, it requires a driving voltage of 100 to 200 V (for example, refer to Reference 1: Japanese Journal of Applied Physics, 1999, Vol. 38, p. L1291-1292). Therefore, the inorganic EL element consumes much power and is difficult to be employed for a small-to-medium-sized display, for example, a display of a cellular phone or the like.

### SUMMARY OF THE INVENTION

In view of the foregoing problem, it is an object of the present invention to provide a light emitting element which can be driven at a low voltage. It is another object of the present invention to provide a light emitting element with high luminescent efficiency. It is another object of the present invention to provide a light emitting element with high luminance. It is another object of the present invention to provide a light emitting element having long-life luminescence. It is another object of the present invention to provide a light emitting device and an electronic device which have reduced power consumption. It is another object of the present invention to provide a light emitting device and an electronic device which can be manufactured at low cost.

The present inventors found that the foregoing problem can be solved by the provision of a barrier layer between a light emitting layer and an electrode.

One aspect of the present invention is a light emitting element including a light emitting layer and a barrier layer between a first electrode and a second electrode. The light emitting layer contains a base material and an impurity element, and the barrier layer is provided so as to be in contact with the first electrode. Light is emitted when a voltage is applied to the first electrode and the second electrode such that a potential of the second electrode becomes higher than a potential of the first electrode.

In the above structure, the thickness of the barrier layer is preferably 1 to 10 nm. In addition, the barrier layer is preferably a metal oxide or a metal nitride. For example, it is preferable that the barrier layer be formed using an oxide of the metal which constitutes the first electrode, because it is possible to form the barrier layer successively after the first electrode in this case.

Furthermore, in the above structure, zinc sulphide, cadmium sulfide, calcium sulfide, yttrium sulphide, gallium sulphide, strontium sulphide, barium sulphide, zinc oxide, yttrium oxide, aluminum nitride, gallium nitride, indium nitride, zinc selenide, zinc telluride, calcium-gallium sulphide, strontium-gallium sulphide, barium-gallium sulphide, or the like can be used as the base material.

In the above structure, the impurity element is preferably a metal element which forms a luminescent center. Alternatively, a plurality of impurity elements may be included with the metal element as the luminescent center, which preferably are: one or more of fluorine (F), chlorine (Cl), bromine (Br), iodine (I), boron (B), aluminum (Al), gallium (Ga), indium (In), or thallium (Tl); and one or more of lithium (Li), sodium (Na), potassium (K), rubidium (Rb), cesium (Cs), nitrogen (N), phosphorus (P), arsenic (As), antimony (Sb), or bismuth (Bi). The metal element as the luminescent center is preferably contained at a concentration of 0.05 to 5 atomic % with respect to the base material. The metal element may be manganese, copper, samarium, terbium, erbium, thulium, europium, cerium, praseodymium, and the like.

Alternatively, in the above structure, a plurality of impurity elements may be included, which preferably are: one or more of copper, silver, gold, platinum, or silicon; and one or more of fluorine, chlorine, bromine, iodine, boron, aluminum, gallium, indium, or thallium.

Alternatively, in the above structure, a plurality of impurity elements may be included, which preferably are: one or more of copper, silver, gold, platinum, or silicon; and one or more of lithium, sodium, potassium, rubidium, cesium, nitrogen, phosphorus, arsenic, antimony, or bismuth.

Alternatively, in the above structure, a plurality of impurity elements may be included, which preferably are: one or more of copper, silver, gold, platinum, or silicon; one or more of fluorine, chlorine, bromine, iodine, boron, aluminum, gallium, indium, or thallium; and one or more of lithium, sodium, potassium, rubidium, cesium, nitrogen, phosphorus, arsenic, antimony, or bismuth.

Furthermore, the present invention includes a light emitting device having the above-described light emitting element. The light emitting device in the present specification includes an image display device, a light emitting device, or a light source (including a lighting device). In addition, the light emitting device of the present invention includes: a module in which a connector such as an FPC (flexible printed circuit), a TAB (tape automated bonding) tape, or a TCP (tape carrier package) which is attached to a panel provided with a light emitting element; a module having a TAB tape or a TCP provided with a printed wiring board at the end thereof; and a module having an IC (integrated circuit) directly mounted on a light emitting element by a COG (chip on glass) method.

Furthermore, the present invention includes an electronic device using the light emitting element of the present invention for the display portion. Accordingly, one feature of the electronic device of the present invention is to include a display portion provided with the above-described light emitting element and a controller for controlling light emission of the light emitting element.

A light emitting element of the present invention has a barrier layer. Through the provision of the barrier layer, carriers can be prevented from passing through it and luminescent efficiency can be improved. In addition, luminance can be improved. Furthermore, a light emitting element with long-life luminescence can be obtained. Furthermore, since the barrier layer is a thin film, a light emitting element which can emit light at a low driving voltage can be obtained.

In addition, since a light emitting device of the present invention has a light emitting element which can be driven at a low voltage, the power consumption can be reduced. Furthermore, since a driver circuit with high voltage resistance is not required, the light emitting device can be manufactured at low cost.

In addition, since an electronic device of the present invention has a light emitting element which can be driven at a low voltage, the power consumption can be reduced. Furthermore, since a driver circuit with high voltage resistance is not required, manufacturing costs of the electronic device can be reduced.

### BRIEF DESCRIPTION OF THE DRAWINGS

In the accompanying drawings:

FIGS. 1A and 1B are views each showing a light emitting element of the present invention;

FIG. 2 is a view showing a light emitting element of the present invention;

FIGS. 3A and 3B are views each showing a light emitting device of the present invention;

FIGS. 4A to 4D are views each showing an electronic device of the present invention;

FIG. 5 is a view showing an electronic device of the present invention;

FIG. 6 is a view showing a light emitting device of the present invention;

FIG. 7 is a view showing a light emitting device of the present invention;

FIG. 8 is a view showing a light emitting device of the present invention;

FIGS. 9A and 9B are views each showing a light emitting device of the present invention;

FIG. 10 is a view showing a light emitting device of the present invention;

FIGS. 11A to 11C are views each showing a light emitting device of the present invention;

FIG. 12 is a view showing a light emitting device of the present invention; and

FIG. 13 is a view showing a light emitting device of the present invention.

### DETAILED DESCRIPTION OF THE INVENTION

Embodiment Modes of the present invention will be explained below with reference to the drawings. However, it is to be easily understood by those skilled in the art that the present invention is not limited to the description below and the modes and details of the present invention can be changed in various ways without departing from the spirit and scope of the present invention. Therefore, the present invention should not be interpreted as being limited to the description of Embodiment Modes below.

### Embodiment Mode 1

In this embodiment mode, a light emitting material used for a light emitting element of the present invention and a formation method thereof will be described. As light emitting materials used in the present invention, a base material and a material constituted by at least one or more kinds of impurity elements to be a luminescent center can be given. It is to be noted that the impurity elements do not include an element that constitutes the base material.

As the base material used for the light emitting material, a sulfide, an oxide, or a nitride can be used. In other words, a compound containing an element of Group 2 and an element of Group 16 of the periodic table, or a compound containing an element of Group 12 and an element of Group 16 can be used. Furthermore, a compound containing an element of Group 3 and an element of Group 16, or a compound containing an element of Group 13 and an element of Group 16 can be used. Furthermore, a compound containing an element of Group 3 and an element of Group 15, or a compound containing an element of Group 13 and an element of Group 15 can be used. As the sulfide, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used, for example. As the oxide, zinc oxide (ZnO), yttrium oxide (Y₂O₃), or the like can be used, for example. As the nitride, aluminum nitride (AlN), gallium nitride (GaN), indium nitride (InN), or the like can be used, for example. Furthermore, zinc selenide (ZnSe), zinc telluride (ZnTe), or the like, or a ternary mixed crystal such as calcium gallium sulfide (CaGa₂S₄), strontium gallium sulfide (SrGa₂S₄), or barium gallium sulfide (BaGa₂S₄), may be used.

As a luminescent center utilizing inner-shell electron transition of a metal ion, manganese (Mn), copper (Cu), samarium (Sm), terbium (Tb), erbium (Er), thulium (Tm), europium (Eu), cerium (Ce), praseodymium (Pr), and the like can be used. It is to be noted that a halogen element such as fluorine (F) or chlorine (Cl) may be added as a charge compensation.

Furthermore, as a luminescent center utilizing donor-acceptor recombination, a light emitting material containing a first impurity element and a second impurity element can be used.

As the first impurity element, copper (Cu), silver (Ag), gold (Au), platinum (Pt), silicon (Si), or the like can be used, for example.

As the second impurity element, fluorine (F), chlorine (Cl), bromine (Br), iodine (I), boron (B), aluminum (Al), gallium (Ga), indium (In), thallium (Tl), or the like can be used, for example.

In the light emitting material according to the present invention, the impurity elements are included in the base material through a solid phase reaction, that is, by a method in which the base material and the impurity elements are weighed, mixed in a mortar, and the mixture is subjected to a reaction by heating in an electric furnace. Specifically, each of the base material, the first impurity element or a compound containing the first impurity element, and the second impurity element or a compound containing the second impurity element is weighed, mixed in a mortar, and then the mixture is heated and baked in an electric furnace. The baking temperature is preferably 700 to 1500° C. This is because a solid phase reaction does not proceed when the temperature is too low and the base material is decomposed when the temperature is too high. It is to be noted that the above mixture may be baked in powder form, but is preferably baked in pallet form.

As the impurity elements in the case of utilizing a solid phase reaction, a compound including the first impurity element and the second impurity element may be used. In this case, the impurity elements are easily diffused and the solid phase reaction easily proceeds, so that a uniform light emitting material can be obtained. Furthermore, since unnecessary impurity elements do not enter, a high-purity light emitting element can be obtained. As the compound including the first impurity element and the second impurity element, copper fluoride (CuF₂), copper chloride (CuCl), copper iodide (CuI), copper bromide (CuBr), copper nitride (Cu₃N), copper phosphide (Cu₃P), silver fluoride (AgF), silver chloride (AgCl), silver iodide (AgI), silver bromide (AgBr), gold chloride (AuCl₃), gold bromide (AuBr₃), platinum chloride (PtCl₂), or the like can be used, for example.

Furthermore, a light emitting material containing a third impurity element instead of the second impurity element can be used.

As the third impurity element, lithium (Li), sodium (Na), potassium (K), rubidium (Rb), cesium (Cs), nitrogen (N), phosphorus (P), arsenic (As), antimony (Sb), bismuth (Bi), or the like can be used, for example.

It is acceptable as long as the concentration of each of the above impurity elements is in the range of 0.01 to 10 atomic %, preferably, in the range of 0.1 to 5 atomic % with respect to the base material.

Furthermore, as a light emitting material having high electric conductivity, a light emitting material containing the above-described base material and the above-described first to third impurity elements can be used. It is acceptable as long as the concentration of each of the impurity elements are in the range of 0.01 to 10 atomic %, preferably, in the range of 0.1 to 5 atomic % with respect to the base material.

As the compound including the second impurity element and the third impurity element, alkali halide such as lithium fluoride (LiF), lithium chloride (LiCl), lithium iodide (LiI), copper bromide (LiBr), sodium chloride (NaCl), boron nitride (BN), aluminum nitride (AlN), aluminum antimonide (AlSb), gallium phosphide (GaP), gallium arsenide (GaAs), indium phosphide (InP), indium arsenide (InAs), indium antimonide (InSb), or the like can be used, for example.

As the light emitting layer, a light emitting material containing the above-described base material and the above-described first to third impurity elements can emit light without requiring hot electrons which are accelerated by a high electric field. That is, there is no need to apply a high voltage to a light emitting element; therefore, a light emitting element which can be operated at a low driving voltage can be obtained. In addition, since light emission can be obtained at a low driving voltage, a light emitting element with reduced power consumption can be obtained. Furthermore, another element to be another luminescent center may be contained.

Alternatively, it is possible to use a light emitting material containing the above-described base material and the second and third impurity elements and the luminescent center utilizing inner-shell electron transition of a metal ion. In this case, the metal ion to be the luminescent center is preferably 0.05 to 5 atomic % with respect to the base material. The concentration of the second impurity element is preferably 0.05 to 5 atomic % with respect to the base material. The concentration of the third impurity element is preferably 0.05 to 5 atomic % with respect to the base material. The light emitting material having such a composition can emit light at a low voltage. Accordingly, a light emitting element which can emit light at a low driving voltage can be obtained, and a light emitting element with reduced power consumption can be obtained. Furthermore, another element to be another luminescent center may be contained.

For example, a light emitting material containing ZnS as the base material, Cu as the first impurity element, Cl and Ga as the second impurity elements, and As as the third impurity element, and further containing Mn as another luminescent center can be used. In order to form a light emitting material like this, the following method can be used. A luminous body (ZnS:Cu, Cl) in which ZnS is combined with copper sulfate (CuS), sulfur, and zinc oxide (ZnO) is added with Mn, and baked in a vacuum for about two to four hours. The baking temperature is preferably 700 to 1500° C. The baked material is crushed so as to have a particle size of 5 to 20 μm, and added with GaAs with a particle size of 1 to 3 μm, then stirred. This mixture is baked in a nitrogen gas stream containing sulfur gas at approximately 500 to 800° C. for two to four hours; whereby the light emitting material can be obtained. A thin film is formed using this light emitting material by a deposition method or the like, which can be used as a light emitting layer of a light emitting element.

By further adding an impurity element to the above-described light emitting material, a crystal system of the light emitting material can be controlled. As an impurity that can control a crystal system, GaP, GaAs, GaSb, InP, InAs, InSb, Si, Ge, and the like, which have a cubic system, can be given. In addition, GaN and InN which have a hexagonal system can be given. In addition, AlP, AlN, AlSb, and the like can be given. By controlling a crystal system of a light emitting material, luminescent efficiency can be improved.

### Embodiment Mode 2

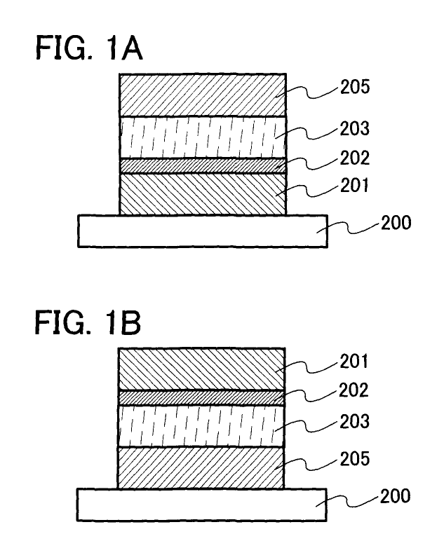

In this embodiment mode, one mode of a light emitting element of the present invention will be described with reference to FIGS. 1A and 1B. In the present specification, an EL layer refers to a layer provided between a first electrode and a second electrode.

The light emitting element described in this embodiment mode has, over a substrate 200, a first electrode 201, a second electrode 205, a light emitting layer 203, and a barrier layer 202. The light emitting element described in this embodiment mode emits light by voltage application between the first electrode 201 and the second electrode 205. In this embodiment mode, a case where light emission is obtained when a potential of the second electrode is made higher than a potential of the first electrode will be described.

The substrate 200 is used as a support of the light emitting element. For the substrate 200, glass, plastic, or the like can be used, for example. It is to be noted that another material may be used as long as it functions as a support during a manufacturing process of the light emitting element.

As the first electrode 201, various metals, an alloy, a conductive compound, a mixture thereof, or the like can be used. Specifically, an example thereof is indium tin oxide (ITO), indium tin oxide containing silicon or silicon oxide, indium zinc oxide (IZO), indium tin oxide containing tungsten oxide and zinc oxide (IWZO), or the like. These conductive metal oxide films are generally formed by sputtering. For example, indium zinc oxide (IZO) can be formed by sputtering using a target in which zinc oxide of 1 to 20 wt % is added to indium oxide. Indium tin oxide containing tungsten oxide and zinc oxide (IWZO) can be formed by sputtering using a target containing tungsten oxide of 0.5 to 5 wt % and zinc oxide of 0.1 to 1 wt % with respect to indium oxide. Alternatively, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), titanium (Ti), titanium nitride (TiN), or the like can be used. It is to be noted that in the case where the first electrode 201 or the second electrode 205 is formed to have a light-transmitting property, a film of a material with low visible light transmittance can also be used for a light-transmitting electrode when formed with a thickness of approximately 1 to 50 nm, preferably, 5 to 20 nm. It is to be noted that the electrode can also be formed by vacuum evaporation, CVD, or a sol-gel method other than sputtering.

The barrier layer 202 is a thin film of an insulating material. As the barrier layer 202, an insulating metal oxide or nitride can be used. For example, an oxide or nitride of aluminum (Al), tungsten (W), chromium (Cr), molybdenum (Mo), titanium (Ti), or the like can be used.

In the case where the barrier layer 202 is formed after the first electrode 201 is formed, the first electrode 201 is formed using a material that can be anodized so that the barrier layer 202 can be formed by anodizing a surface of the first electrode 201. For example, Al is used for the first electrode, and by anodic oxidation, aluminum oxide (AlₓO_{y}) can be formed as a barrier layer. Alternatively, Ti may be used for the first electrode, and by anodic oxidation, titanium oxide (TiOₓ) can be formed as a barrier layer. In the case where the barrier layer is formed by anodic oxidation, barrier layers with different film qualities (a dense anodized film, a porous anodized film, and the like) can be formed depending on a condition of the anodic oxidation. In addition, the thickness of the barrier layer can be controlled.

For example, an ethylene glycol solution of tartaric acid of 3% which is neutralized with an ammonium hydroxide so that PH thereof is adjusted to be 6.92 is used as an electrolyte solution. By using platinum as a cathode and the first electrode aluminum as an anode, a current (formation current and ultimate voltage are set to be 5 to 6 mA and 40 to 100 V, respectively) is applied between the electrodes in this electrolyte solution, whereby an anodized film with a dense, strong film quality can be formed on the surface of the aluminum film. The thickness of this anodized film can be roughly controlled by a voltage applied.

It is to be noted that a sputtering method, a sol-gel method or the like may be used for forming the barrier layer 202, other than the above-described anodic oxidation.

The thickness of the barrier layer 202 is preferably 0.1 to 10 nm so as to suppress an increase of a driving voltage. Through the provision of the barrier layer 202, carriers injected in the light emitting layer can be prevented from passing through the light emitting layer without contributing to light emission and flowing to an electrode. In this way, luminescent efficiency can be improved.

The light emitting layer 203 is a layer containing the light emitting material described in Embodiment Mode 1, which can be formed using various methods. The film thickness is not particularly limited, but preferably in the range of 10 to 1000 nm.

As the second electrode 205, various metals, an alloy, a conductive compound, a mixture thereof, or the like can be used. Specifically, an example thereof is indium tin oxide (ITO), indium tin oxide containing silicon or silicon oxide, indium zinc oxide (IZO), indium tin oxide containing tungsten oxide and zinc oxide (IWZO), or the like. These conductive metal oxide films are generally formed by sputtering. For example, indium zinc oxide (IZO) can be formed by sputtering using a target in which zinc oxide of 1 to 20 wt % is added to indium oxide. Indium tin oxide containing tungsten oxide and zinc oxide (IWZO) can be formed by sputtering using a target containing tungsten oxide of 0.5 to 5 wt % and zinc oxide of 0.1 to 1 wt % with respect to indium oxide. Alternatively, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), titanium (Ti), a nitride of the metal material (for example, titanium nitride: TiN), or the like can be used. It is to be noted that in the case where the first electrode 201 or the second electrode 205 is formed to have a light-transmitting property, a film of a material with low visible light transmittance can also be used for a light-transmitting electrode when formed with a thickness of approximately 1 to 50 nm, preferably, 5 to 20 nm. It is to be noted that the electrode can also be formed by vacuum evaporation, CVD, or a sol-gel method other than sputtering.

However, light emission is extracted out through the first electrode 201 or the second electrode 205; therefore, at least one of the first electrode 201 and the second electrode 205 needs to have a light-transmitting property.

Although a structure in which the first electrode 201 is provided on the substrate 200 side is shown in FIG. 1A, a structure in which layers are stacked in the opposite order to that of FIG. 1A may also be employed, wherein the second electrode 205 is provided on the substrate 200 side, as shown in FIG. 1B. In the case of the structure shown in FIG. 1B, the barrier layer 202 is preferably formed by a sputtering method or a sol-gel method.

The light emitting element of the present invention has a barrier layer formed of a thin film of an insulating material. Through the provision of the barrier layer, carriers injected in a light emitting layer can be prevented from passing through the light emitting layer without contributing to light emission and flowing to an electrode. In this way, luminescent efficiency can be improved.

It is to be noted that this embodiment mode can be combined appropriately with other embodiment modes.

### Embodiment Mode 3

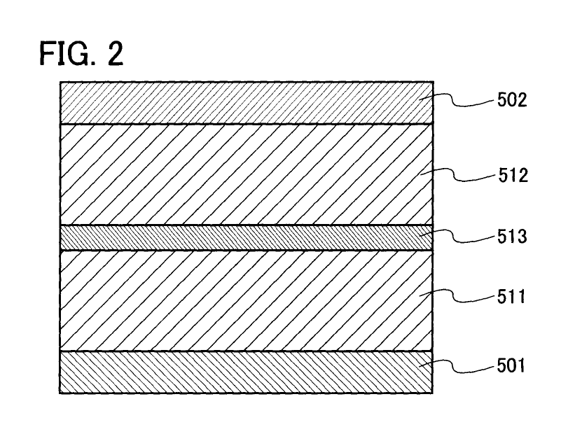

In this embodiment mode, a mode of a light emitting element with a structure in which a plurality of light emitting units of the present invention are stacked (hereinafter referred to as a stacked element) will be described with reference to FIG. 2. This light emitting element has a plurality of light emitting units between a first electrode and a second electrode.

In FIG. 2, a first light emitting unit 511 and a second light emitting unit 512 are stacked between a first electrode 501 and a second electrode 502. Materials similar to those in Embodiment Mode 2 can be applied to the first electrode 501 and the second electrode 502. Furthermore, the first light emitting unit 511 and the second light emitting unit 512 have the same structure, which is similar to the structure described in Embodiment Mode 2. In other words, a structure in which a barrier layer, a light emitting layer, and a layer containing a composite material are stacked similarly to Embodiment Mode 2 can be applied to the light emitting unit.

A charge generation layer 513 contains a complex of an organic compound and a metal oxide. The complex of an organic compound and a metal oxide is constituted by an organic compound and a metal oxide such as V₂O₅, MoO₃, or WO₃. As the organic compound, various compounds such as an aromatic amine compound, a carbazole derivative, aromatic hydrocarbon, and a high molecular compound (oligomer, dendrimer, polymer, or the like) can be used. It is to be noted that the organic compound having hole mobility of 10⁻⁶ cm²/Vs or greater is preferably used as a hole transporting organic compound. However, besides the above materials, others may be used as long as the material has a higher hole transporting property than an electron transporting property. Since the complex of an organic compound and a metal oxide is excellent in carrier injection and carrier transportation, it can realize low voltage drive and low current drive.

The charge generation layer 513 may be formed using a combination of the complex of an organic compound and a metal oxide, and other materials. For example, a layer containing the complex of an organic compound and a metal oxide, and a layer containing a compound selected from electron donating materials and a compound having a high electron transporting property may be combined to form the charge generation layer 513. Alternatively, a layer containing the complex of an organic compound and a metal oxide, and a transparent conductive film may be combined to form the charge generation layer 513.

In any case, other combinations for forming the charge generation layer 513 interposed between the first light emitting unit 511 and the second light emitting unit 512 are acceptable as long as the charge generation layer 513 injects electrons to the light emitting unit on one side and injects holes to the light emitting unit on the other side when a voltage is applied to the first electrode 501 and the second electrode 502.

Although the light emitting element having two light emitting units is described in this embodiment mode, a light emitting element in which three or more light emitting units are stacked can be employed in a similar way. Arrangement of a plurality of light emitting units that are partitioned by an electrically insulating charge generation layer between a pair of electrodes, as in the light emitting element of this embodiment mode, can realize an element having long-life in a high luminance region, while keeping a current density low. In addition, when the light emitting element is applied to a lighting system for example, uniform light emission in a large area is possible because voltage drop due to resistance of an electrode material can be decreased. Furthermore, in the case where the light emitting element is applied to a display device, a display device with a high contrast which can be driven at a low voltage and consumes low power can be realized.

It is to be noted that this embodiment mode can be appropriately combined with other embodiment modes.

### Embodiment Mode 4

In this embodiment mode, a light emitting device having a light emitting element manufactured by applying the present invention will be described.

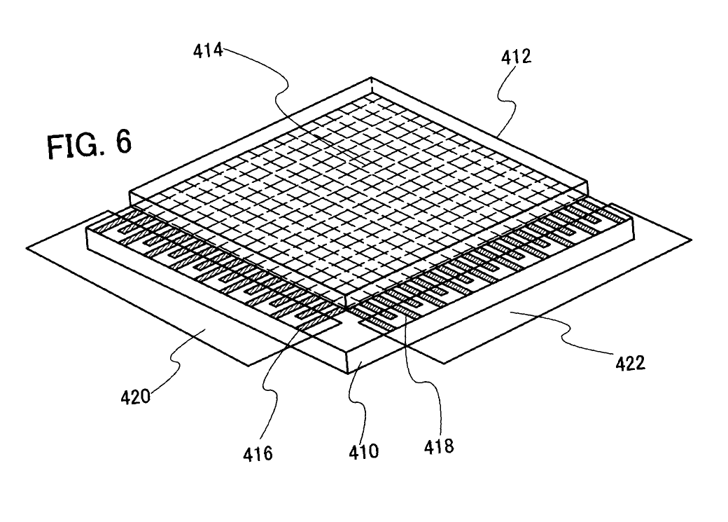

In this embodiment mode, a display device as one mode of the light emitting device will be described with reference to FIGS. 6, 7, 8, 9A, 9B, and 10. FIG. 6 is a schematic configuration diagram showing a main part of the display device.

Over a substrate 410, a first electrode 416 and a second electrode 418 that extends in a direction intersecting with the first electrode 416 are provided. An EL layer similar to those described in Embodiment Modes 2 and 3 is provided at least at the intersection of the first electrode 416 and the second electrode 418, whereby a light emitting element is formed. In a display device of FIG. 6, a plurality of first electrodes 416 and a plurality of second electrodes 418 are disposed and light emitting elements to be pixels are arranged in a matrix, whereby a display portion 414 is formed. In the display portion 414, light emission and non-light emission of each light emitting element are controlled by controlling potentials of the first electrode 416 and the second electrode 418. In this manner, the display portion 414 can display moving images and still images.

In this display device, a signal for displaying a picture is applied to each of the first electrode 416 extending in one direction over the substrate 410 and the second electrode 418 that intersects with the first electrode 416, and light emission and non-light emission of a light emitting element are selected. In other words, this is a simple matrix display device of which the pixel is driven solely by a signal given from an external circuit. A display device like this has a simple structure and can be manufactured easily even when the area is enlarged.

A counter substrate 412 may be provided if necessary, and it can serve as a protective member when provided adjusting to the position of the display portion 414. The counter substrate 412 is not required to be a hard plate member; a resin film or a resin material may be applied instead. The first electrode 416 and the second electrode 418 are led to ends of the substrate 410 to form terminals to be connected to external circuits. In other words, the first electrode 416 and the second electrode 418 are in contact with flexible wiring boards 420 and 422 at the ends of the substrate 410. The external circuits include a power supply circuit, a tuner circuit, or the like, in addition to a controller circuit that controls a video signal.

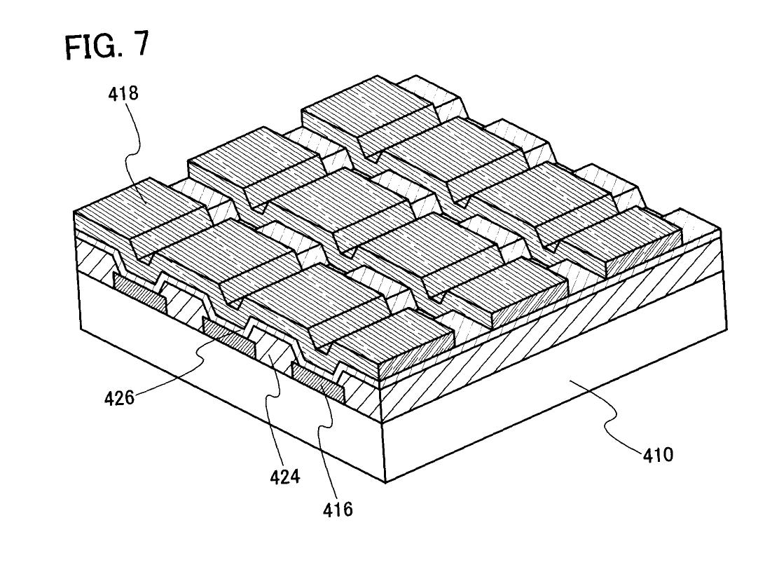

FIG. 7 is a partially enlarged view showing a structure of the display portion 414. A partition layer 424 is formed on an edge portion of the first electrode 416 formed over the substrate 410. An EL layer 426 is formed at least over an exposed surface of the first electrode 416. The second electrode 418 is formed over the EL layer 426. The second electrode 418 intersects with the first electrode 416, so it extends over the partition layer 424 as well. The partition layer 424 is formed using an insulating material so that short-circuiting between the first electrode 416 and the second electrode 418 is prevented. In a portion where the partition layer 424 covers the edge of the first electrode 416, an edge portion of the partition layer 424 is sloped so as not to make a steep step, and has a so-called tapered shape. In the case where the partition layer 424 has such a shape, coverage of the EL layer 426 and the second electrode 418 improves, and defects such as cracks or tears can be prevented.

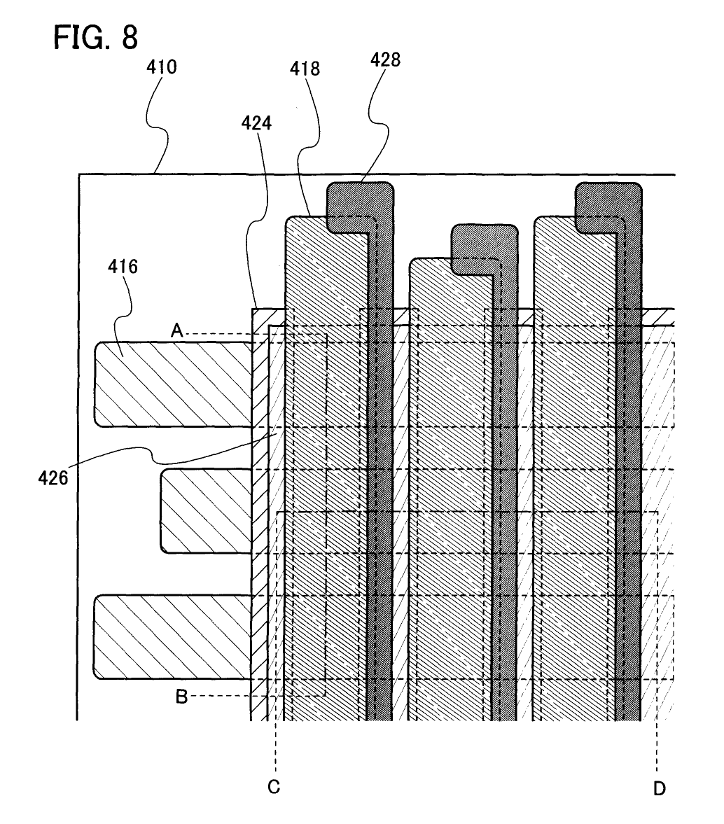

FIG. 8 is a plane view of the display portion 414, which shows the arrangement of the first electrode 416, the second electrode 418, the partition layer 424, and the EL layer 426. In the case where the second electrode 418 is formed of an oxide transparent conductive film such as indium tin oxide or zinc oxide, an auxiliary electrode 428 is preferably provided so as to reduce the resistance loss. In this case, the auxiliary electrode 428 may be formed using a refractory metal such as titanium, tungsten, chromium, or tantalum, or a combination of the refractory metal and a low resistance metal such as aluminum or silver.

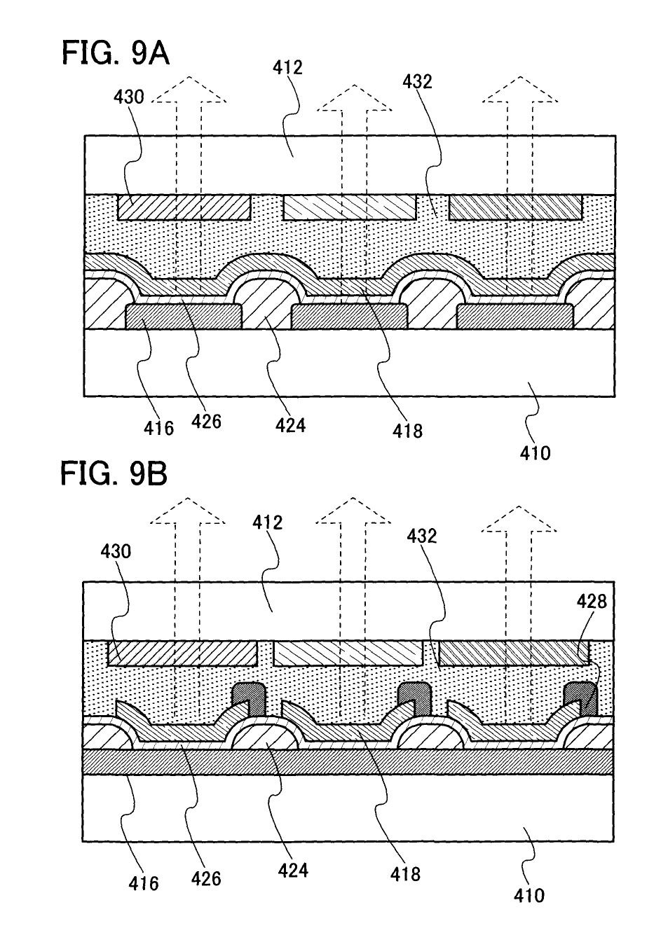

FIGS. 9A and 9B show cross-sectional views taken along the line A-B and the line C-D in FIG. 8, respectively. FIG. 9A is a cross-sectional view in which the first electrodes 416 are lined up, and FIG. 9B is a cross-sectional view in which the second electrodes 418 are lined up. The EL layer 426 is formed at the intersections of the first electrode 416 and the second electrode 418, and light emitting elements are formed in these portions. The auxiliary electrode 428 shown in FIG. 9B is provided over the partition layer 424 and in contact with the second electrode 418. The auxiliary electrode 428 formed over the partition layer 424 does not block light from the light emitting element formed at the intersection of the first electrode 416 and the second electrode 418; therefore, the emitted light can be efficiently utilized. In addition, with this structure, short-circuiting between the auxiliary electrode 428 and the first electrode 416 can be prevented.

In FIGS. 9A and 9B, examples in which color conversion layers 430 are placed on the counter substrate 412 are shown. The color conversion layer 430 converts the wavelength of light emitted from the EL layer 426 so that the color of the light emission is changed. In this case, light emitted from the EL layer 426 is preferably blue light or ultraviolet light with high energy. When the color conversion layers 430 for converting light to red, green, and blue light are arranged, a display device that performs RGB full-color display can be obtained. Furthermore, the color conversion layer 430 can be replaced by a colored layer (color filter). In this case, the EL layer 426 may be made to emit white light. A filler 432 may be appropriately provided so as to fix the substrate 410 and the counter substrate 412 to each other.

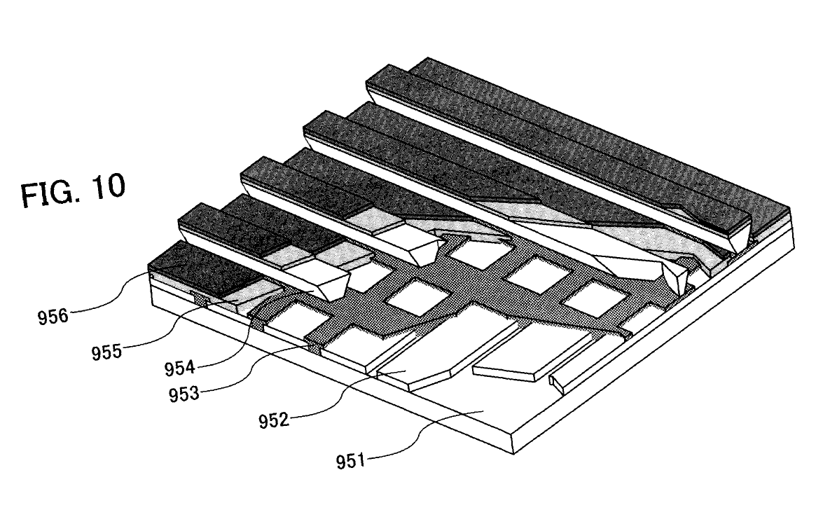

Another structure of the display portion 414 is shown in FIG. 10. In the structure shown in FIG. 10, an edge portion of a first electrode 952 is covered with an insulating layer 953. In addition, a partition layer 954 is provided over the insulating layer 953. Sidewalls of the partition layer 954 are sloped such that a distance between one sidewall and the other sidewall becomes narrower as the sidewalls gets closer to the substrate surface 951. In other words, a cross section in the minor axis of the partition layer 954 is a trapezoidal shape of which the lower base (the side which is in the same direction as the plane direction of the insulating layer 953 and in contact with the insulating layer 953) is shorter than the upper base (the side which is in the same direction as the plane direction of the insulating layer 953 and not in contact with the insulating layer 953). In this way, when the partition layer 954 is provided, an EL layer 955 and a second electrode 956 can be formed in a self-aligning manner by utilizing the partition layer 954.

In the above, when the first electrode 952 is formed using aluminum, titanium, tantalum or the like, and the second electrode 956 is formed using indium oxide, indium tin oxide (ITO), indium zinc oxide, or zinc oxide; a display device having the display portion 414 on the counter substrate 412 side can be obtained. In this case, when a thin oxide film is formed over a surface of the first electrode 952, a barrier layer is formed and luminous efficiency can be improved because of a carrier blocking effect. In the case where the first electrode 952 is formed using indium oxide, indium tin oxide (ITO), indium zinc oxide, or zinc oxide, and the second electrode 956 is formed using aluminum, titanium, tantalum or the like; a display device having the display portion 414 on the substrate 410 side can be obtained. Furthermore, in the case where both the first electrode 952 and the second electrode 956 are formed of transparent electrodes, a dual emission display device can be obtained.

Since the light emitting element in the display device of this embodiment mode emits light at a low voltage, a booster circuit or the like is not required; therefore, the structure of the device can be simplified. In addition, an EL layer in the light emitting element is not required to be made thick; therefore, an even thinner display device can be realized.

### Embodiment Mode 5

In this embodiment mode, a light emitting device including the light emitting element manufactured by applying the present invention will be described.

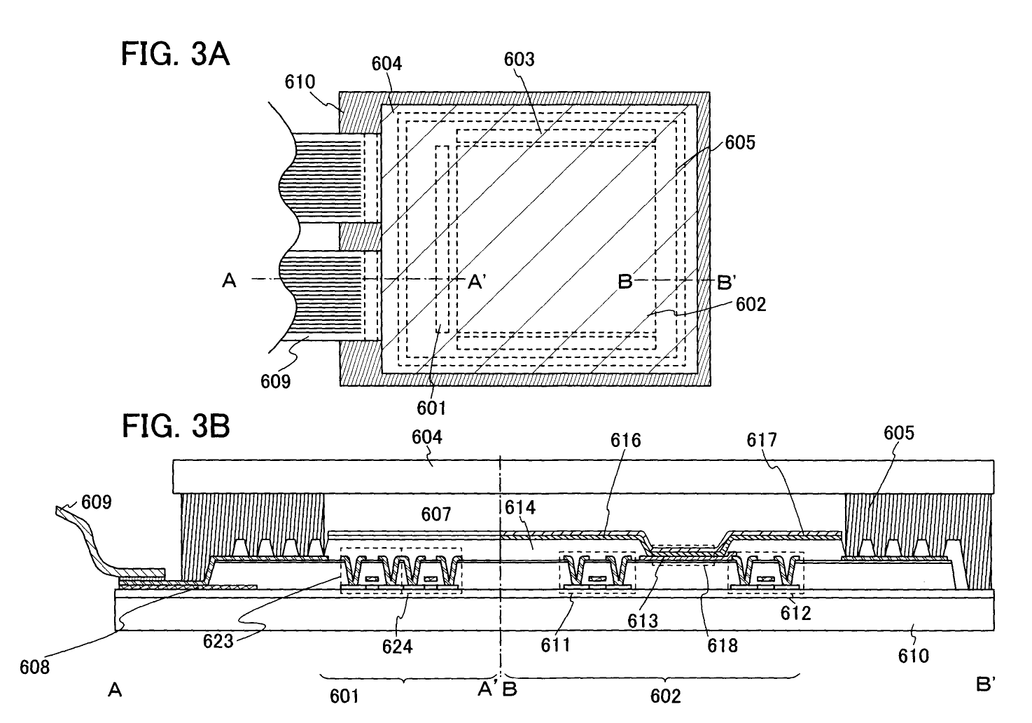

In this embodiment mode, an active light emitting device in which the drive of a light emitting element is controlled by a transistor will be described. In this embodiment mode, a light emitting device including the light emitting element manufactured by applying the present invention in a pixel portion will be described with reference to FIGS. 3A and 3B. FIG. 3A is a top view showing the light emitting device and FIG. 3B is a cross-sectional view of FIG. 3A taken along lines A-A′ and B-B′. A reference numeral 601 denotes a driver circuit portion (a source side driver circuit); 602, a pixel portion; and 603, a driver circuit portion (a gate side driver circuit), each of which is indicated by dashed line. A reference numeral 604 denotes a sealing substrate; 605, a sealant; and a portion surrounded by the sealant 605 is a space 607.

It is to be noted that a lead wiring 608 is a wiring for transmitting signals to be input to the source side driver circuit 601 and the gate side driver circuit 603 and receives a video signal, a clock signal, a start signal, a reset signal, and the like from an FPC (Flexible Printed Circuit) 609 which is an external input terminal. Although only the FPC is shown here, the FPC may be provided with a printed wiring board (PWB). The light emitting device in the present specification includes not only a main body of the light emitting device but also the light emitting device with an FPC or a PWB attached.

Next, a cross-sectional structure will be explained with reference to FIG. 3B. The driver circuit portions and the pixel portion are formed over an element substrate 610. Here, the source side driver circuit 601, which is one of the driver circuit portions, and one pixel in the pixel portion 602, are shown.

A CMOS circuit that is a combination of an n-channel TFT 623 and a p-channel TFT 624 is formed as the source side driver circuit 601. The driver circuit may be a known CMOS circuit, PMOS circuit, or NMOS circuit. A driver integration type in which a driver circuit is formed over a substrate is described in this embodiment mode, but it is not necessarily required and a driver circuit can be formed not over a substrate but outside of a substrate. The structure of the TFT is not particularly limited; a staggered TFT may be employed, or an inversely staggered TFT may be employed. Crystallinity of a semiconductor film used for the TFT is not particularly limited either; an amorphous semiconductor film may be used, or a crystalline semiconductor film may be used. Furthermore, a semiconductor material is not particularly limited; an inorganic compound may be used, or an organic compound may be used.

The pixel portion 602 includes a plurality of pixels, each of which includes a switching TFT 611, a current control TFT 612, and a first electrode 613 which is electrically connected to a drain of the current control TFT 612. It is to be noted that an insulator 614 is formed to cover an edge of the first electrode 613. Here, a positive type photosensitive acrylic resin film is used.

The insulator 614 is formed to have a curved surface with curvature at an upper edge or a lower edge thereof in order to obtain favorable coverage. For example, in the case of using positive type photosensitive acrylic as a material of the insulator 614, the insulator 614 is preferably formed to have a curved surface with a curvature radius (0.2 to 3 μm) only at an upper edge. Either a negative type which becomes insoluble in an etchant by light irradiation or a positive type which becomes soluble in an etchant by light irradiation can be used as the insulator 614.

An EL layer 616 and a second electrode 617 are formed over the first electrode 613. At least one of the first electrode 613 and the second electrode 617 has a light-transmitting property, through which light emitted from the EL layer 616 can be taken out.

The EL layer 616 is the EL layer that is described in Embodiment Modes 2 and 3.

The first electrode 613, the EL layer 616, and the second electrode 617 can be formed by various methods. Specifically, they can be formed by a vacuum evaporation method such as a resistance heating evaporation method or an electron beam (EB) evaporation method, a physical vapor deposition (PVD) method such as a sputtering method, a chemical vapor deposition (CVD) method such as a metal organic CVD method or a low pressure hydride transport CVD method, an atomic layer epitaxy (ALE) method, or the like. Furthermore, an inkjet method, a spin coating method, or the like can be used. In addition, each layer or each electrode may be formed by using a different film formation method.

By attaching the sealing substrate 604 to the element substrate 610 with the sealant 605, a light emitting element 618 is provided in the space 607 surrounded by the element substrate 610, the sealing substrate 604, and the sealant 605. The space 607 is filled with filler, but there is also a case where the space 607 is filled with the sealant 605 or filled with an inert gas (nitrogen, argon, or the like).

An epoxy-based resin is preferably used as the sealant 605. The material preferably allows as little moisture and oxygen as possible to penetrate. As the sealing substrate 604, a plastic substrate formed of FRP (Fiberglass-Reinforced Plastics), PVF (polyvinyl fluoride), myler, polyester, acrylic, or the like can be used besides a glass substrate or a quartz substrate.

As described above, the light emitting device including the light emitting element manufactured by applying the present invention can be obtained.

The light emitting device shown in this embodiment mode includes the light emitting element described in Embodiment Modes 2 and 3. The light emitting element described in Embodiment Modes 2 and 3 can be operated at a low drive voltage. In addition, it can achieve high luminescent efficiency. Thus, a light emitting device with reduced power consumption can be obtained.

In addition, since the light emitting device shown in this embodiment mode does not require a driver circuit with high voltage resistance, manufacturing costs of the light emitting device can be reduced. In addition, reductions in weight of the light emitting device and size of a driver circuit portion can be achieved.

### Embodiment Mode 6

In this embodiment mode, an electronic device of the present invention which includes the light emitting device described in Embodiment Modes 4 and 5 will be described. The electronic device described in this embodiment mode includes the light emitting element described in Embodiment Modes 2 and 3. An electronic device with reduced power consumption can be provided because it includes a light emitting element with reduced drive voltage.

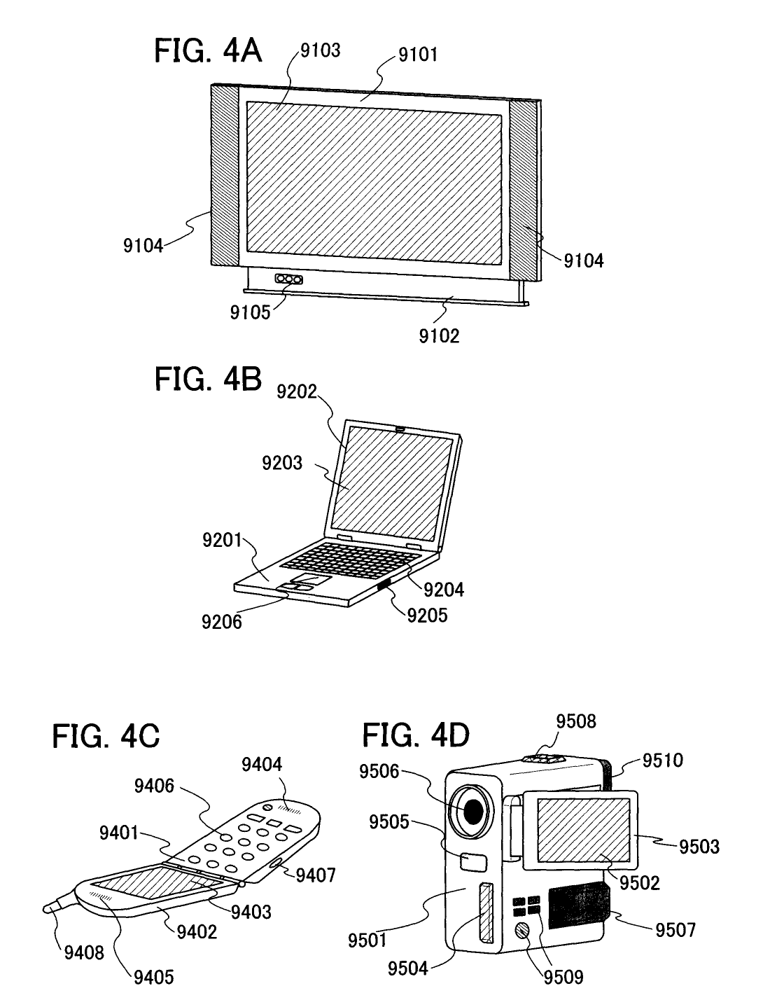

Examples of the electronic device manufactured by applying the present invention are as follows: a camera such as a video camera or a digital camera, a goggle type display, a navigation system, a sound reproducing device (a car audio system, an audio component, or the like), a computer, a game machine, a portable information terminal (a mobile computer, a cellular phone, a mobile game machine, an electronic book, or the like), an image reproducing device having a recording medium (specifically, a device for reproducing a recording medium such as a digital versatile disc (DVD) and having a display for displaying the image), and the like. Specific examples of these electronic devices are shown in FIGS. 4A to 4D.

FIG. 4A shows a television device according to the present invention, which includes a chassis 9101, a support base 9102, a display portion 9103, a speaker portion 9104, a video input terminal 9105, and the like. In this television device, the display portion 9103 includes light emitting elements similar to those described in Embodiment Modes 2 and 3, which are arranged in a matrix. The light emitting element has features of high luminescent efficiency and low drive voltage. In addition, short-circuiting due to impact from the outside can also be prevented. The display portion 9103 which includes the light emitting element also has a similar feature. Therefore, in this television device, image quality does not deteriorate and power consumption is reduced. With such features, a deterioration compensation function and a power supply circuit can be significantly reduced or downsized; whereby reductions in size and weight of the chassis 9101 and the support base 9102 can be achieved. Since a reduction in power consumption, an improvement in image quality, and reductions in size and weight are achieved in the television device of the present invention, a product which is suitable for the living environment can be provided.

FIG. 4B shows a computer according to the present invention, which includes a main body 9201, a chassis 9202, a display portion 9203, a keyboard 9204, an external connection port 9205, a pointing mouse 9206, and the like. In this computer, the display portion 9203 includes light emitting elements similar to those described in Embodiment Modes 2 and 3, which are arranged in a matrix. The light emitting element has features of high luminescent efficiency and low drive voltage. In addition, short-circuiting due to impact from the outside, or the like can also be prevented. The display portion 9203 which includes the light emitting element has a similar feature. Therefore, in this computer, image quality does not deteriorate and power consumption is reduced. With such features, a deterioration compensation function and a power supply circuit can be significantly reduced or downsized in the computer; whereby reductions in size and weight of the main body 9201 and the chassis 9202 can be achieved. Since a reduction in power consumption, an improvement in image quality, and reductions in size and weight are achieved in the computer of the present invention, a product which is suitable for the environment can be provided. In addition, it becomes portable, and a computer including a display portion resistant to impact from the outside when being carried can be provided.

FIG. 4C shows a cellular phone according to the present invention, which includes a main body 9401, a chassis 9402, a display portion 9403, an audio input portion 9404, an audio output portion 9405, an operation key 9406, an external connection port 9407, an antenna 9408, and the like. In this cellular phone, the display portion 9403 includes light emitting elements similar to those described in Embodiment Modes 2 and 3, which are arranged in a matrix. The light emitting element has features of high luminescent efficiency and low drive voltage. In addition, short-circuiting due to impact from the outside can also be prevented. The display portion 9403 which includes the light emitting element also has a similar feature. Therefore, in this cellular phone, image quality does not deteriorate and power consumption is reduced. With such features, a deterioration compensation function and a power supply circuit can be significantly reduced or downsized in the cellular phone; whereby reductions in size and weight of the main body 9401 and the chassis 9402 can be achieved. Since a reduction in power consumption, an improvement in image quality, and reductions in size and weight are achieved in the cellular phone of the present invention, a product which is suitable for being carried can be provided. In addition, a product including a display portion resistant to impact from the outside when being carried can also be provided.

FIG. 4D shows a camera according to the present invention, which includes a main body 9501, a display portion 9502, a chassis 9503, an external connection port 9504, a remote control receiving portion 9505, an image receiving portion 9506, a battery 9507, an audio input portion 9508, operation keys 9509, an eye piece portion 9510, and the like. In this camera, the display portion 9502 includes light emitting elements similar to those described in Embodiment Modes 2 and 3, which are arranged in a matrix. The light emitting element has features of high luminescent efficiency, low drive voltage, and capability of preventing short-circuiting due to impact from the outside, or the like. The display portion 9502 which includes the light emitting element also has similar features. Therefore, in this camera, image quality does not deteriorate and power consumption is reduced. With such features, a deterioration compensation function and a power supply circuit can be significantly reduced or downsized in the camera; whereby reductions in size and weight of the main body 9501 can be achieved. Since a reduction in power consumption, an improvement in image quality, and reductions in size and weight are achieved in the camera of the present invention, a product which is suitable for being carried can be provided. In addition, a product including a display portion resistant to impact from the outside when being carried can also be provided.

As described above, the applicable range of the display device manufactured by applying the present invention is so wide that the display device can be applied to electronic devices of various fields. By applying the present invention, an electronic device including a display portion which consumes less power and has high reliability can be manufactured.

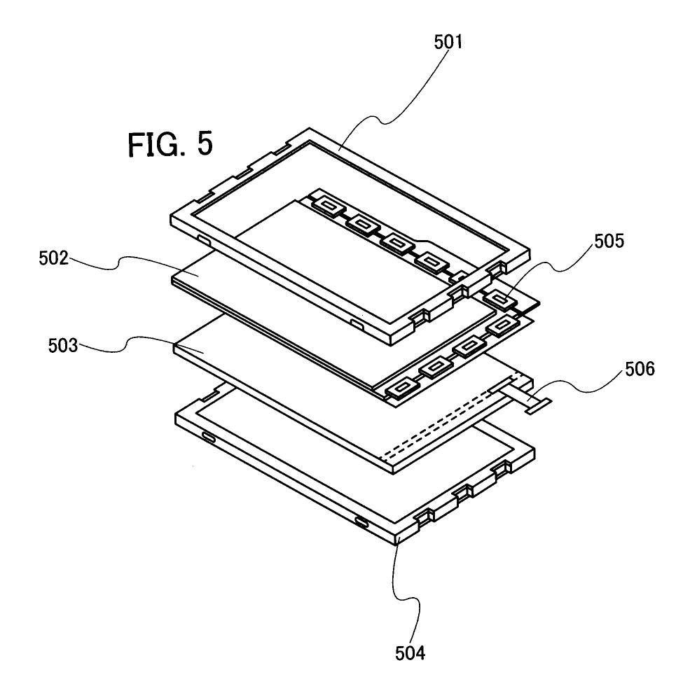

In addition, the light emitting device to which the present invention is applied has a light emitting element with high luminescent efficiency, and can also be used as a lighting system. One mode of using the light emitting element to which the present invention is applied as a lighting system will be described with reference to FIG. 5.

FIG. 5 shows an example of a liquid crystal display device using the light emitting device to which the present invention is applied as a backlight. The liquid crystal display device shown in FIG. 5 includes a chassis 501, a liquid crystal layer 502, a backlight 503, and a chassis 504. The liquid crystal layer 502 is connected to a driver IC 505. The light emitting device of the present invention is used as the backlight 503, to which a voltage is supplied through a terminal 506.

By using the light emitting device of the present invention as a backlight of a liquid crystal display device, a backlight with high luminance and long life can be obtained; whereby the quality as a display device is improved. Since the light emitting device of the present invention is a plane-emission light emitting device and can be formed to have a large area, a larger-area backlight can be obtained and a larger-area liquid crystal display device can also be obtained. Furthermore, the light emitting element is thin and consumes low power; therefore, reductions in thickness and power consumption of the display device can also be achieved.

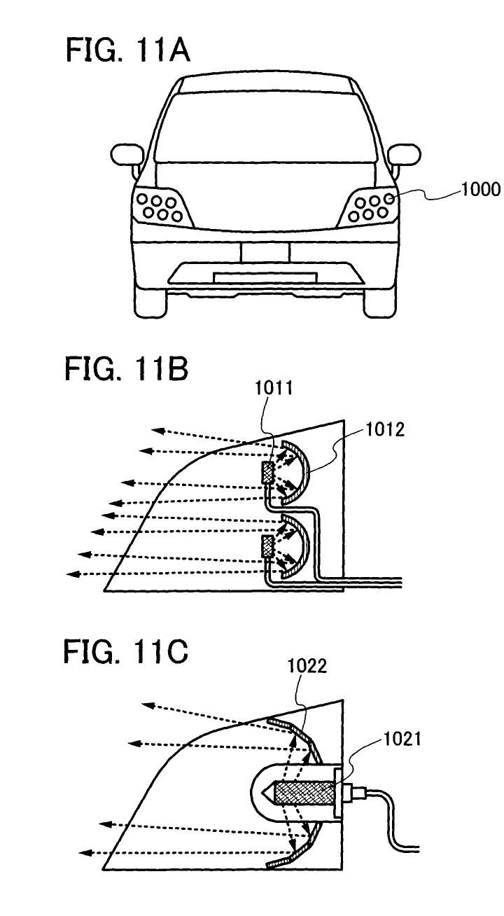

Furthermore, since a light emitting device to which the present invention is applied can emit light with high luminance, it can be used as a headlight of a car, bicycle, ship, or the like. FIGS. 11A to 11C show an example in which a light emitting device to which the present invention is applied is used as a headlight of a car. FIG. 11B is an enlarged cross-sectional view showing a headlight 1000 of FIG. 11A. In FIG. 11B, the light emitting device of the present invention is used as a light source 1011. Light emitted from the light source 1011 is reflected by a reflector 1012 and extracted to external. As shown in FIG. 11B, light with higher luminance can be obtained by using a plurality of light sources. FIG. 11C is an example in which a light emitting device of the present invention that is manufactured in a cylindrical shape is used as a light source. Light emitted from the light source 1021 is reflected by a reflector 1022 to the outside.

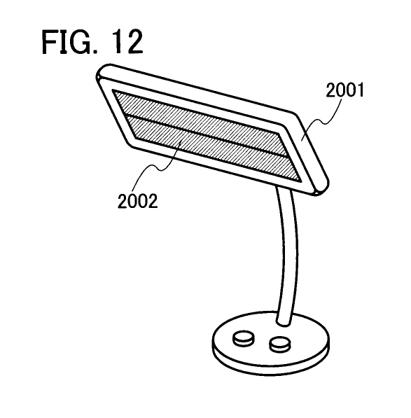

FIG. 12 shows an example in which a light emitting device to which the present invention is applied is used as a desk lamp that is one of lighting systems. The desk lamp shown in FIG. 12 includes a chassis 2001 and a light source 2002, and the light emitting device of the present invention is used as the light source 2002. Since the light emitting device of the present invention is capable of emitting light with high luminance, this desk lamp can illuminate hands when fine handwork is required or the like.

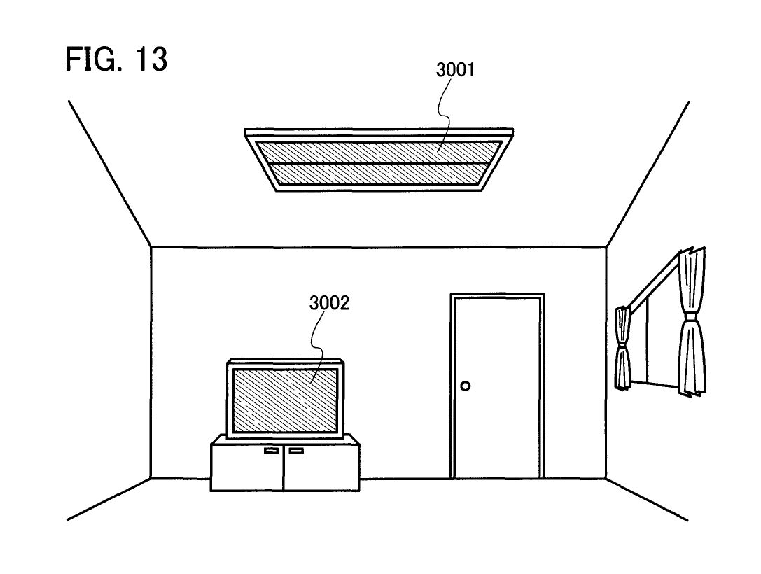

FIG. 13 shows an example in which a light emitting device to which the present invention is applied is used as an interior lighting system 3001. Since the light emitting device of the present invention can have a large area, it can be used as a large-area lighting system. In addition, since the light emitting device of the present invention is thin and consumes low power, it can be used as a thin lighting system with low power consumption. As shown in the drawing, a television device of the present invention as explained in FIG. 4A may be set in a room where the light emitting device to which the present invention is applied is used as the indoor lighting system 3001, and public broadcasting or movies can be appreciated there. In such a case, powerful images in a bright room can be appreciated without concerns about electricity costs, because both the lighting system and the television device 3002 consume low power

The lighting systems are not limited to those exemplified in FIGS. 11A to 11C, 12, and 13, and the light emitting device of the present invention can be applied to lighting systems in various modes, including lighting systems for houses and public facilities. The light emitting medium of the lighting system of the present invention is a thin film, which increases design freedom. Accordingly, various elaborately-designed products can be provided to the marketplace.

This application is based on Japanese Patent Application serial No. 2006-041644 filed in Japan Patent Office on Feb. 17, 2006, the entire contents of which are hereby incorporated by reference.

What is claimed is:

1. A light emitting device comprising:
a light emitting element comprising a light emitting layer and a barrier layer interposed between a first electrode and a second electrode,
wherein the light emitting layer contains a base material and an impurity element which forms a luminescent center,
wherein the barrier layer is provided in contact with the first electrode, and
wherein light emission is obtained when a voltage is applied to the first electrode and the second electrode such that a potential of the second electrode is higher than a potential of the first electrode.

2. A light emitting device according to claim 1, wherein the thickness of the barrier layer is 1 to 10 nm.

3. A light emitting device according to claim 1, wherein the barrier layer comprises a metal oxide or a metal nitride.

4. A light emitting device according to claim 1, wherein the barrier layer comprises an oxide of a metal constituting the first electrode.

5. A light emitting device according to claim 1, wherein the base material is at least one of zinc sulphide, cadmium sulfide, calcium sulfide, yttrium sulphide, gallium sulphide, strontium sulphide, barium sulphide, zinc oxide, yttrium oxide, aluminum nitride, gallium nitride, indium nitride, zinc selenide, zinc telluride, calcium-gallium sulphide, strontium-gallium sulphide, and barium-gallium sulphide.

6. A light emitting device according to claim 1, wherein the impurity element is a metal element which forms the luminescent center.

7. A light emitting device according to claim 6, further comprising a second impurity element which is at least one of fluorine (F), chlorine (Cl), bromine (Br), iodine (I), boron (B), aluminum (Al), gallium (Ga), indium (In), and thallium (Tl), and a third impurity element which is at least one of lithium (Li), sodium (Na), potassium (K), rubidium (Rb), cesium (Cs), nitrogen (N), phosphorus (P), arsenic (As), antimony (Sb), and bismuth (Bi).

8. A light emitting device according to claim 6, wherein the metal element is contained at a concentration of 0.05 to 5 atomic % with respect to the base material.

9. A light emitting device according to claim 6, wherein the metal element is at least one of manganese, copper, samarium, terbium, erbium, thulium, europium, cerium, and praseodymium.

10. A light emitting device according to claim 1, further comprising a second impurity element which is at least one of copper, silver, gold, platinum, and silicon, and a third impurity element which is at least one of fluorine, chlorine, bromine, iodine, boron, aluminum, gallium, indium, and thallium.

11. A light emitting device according to claim 1, further comprising a second impurity element which is at least one of copper, silver, gold, platinum, and silicon, and a third impurity element which is at least one of lithium, sodium, potassium, rubidium, cesium, nitrogen, phosphorus, arsenic, antimony, and bismuth.

12. A light emitting device according to claim 1, further comprising a second impurity element which is at least one of copper, silver, gold, platinum, and silicon, and a third impurity element which is at least one of fluorine, chlorine, bromine, iodine, boron, aluminum, gallium, indium, and thallium, and a fourth impurity element which is at least one of lithium, sodium, potassium, rubidium, cesium, nitrogen, phosphorus, arsenic, antimony, and bismuth.

13. A light emitting device according to claim 1, further comprising a controller for controlling light emission of the light emitting element.

14. An electronic device according to claim 1, further comprising a display portion, wherein the display portion includes the light emitting element, and a controller for controlling light emission of the light emitting element.
